(19) United States
(12) Patent Application Publication
(10) Pub. No.: US 2023/0178436 A1
(43) Pub. Date: Jun. 8, 2023

(54) 3D NANO SHEET WITH HIGH DENSITY 3D METAL ROUTING

(71) Applicant: Tokyo Electron Limited, Tokyo (JP)

(72) Inventors: Mark I. GARDNER, Cedar Creek, TX (US); H. Jim FULFORD, Marianna, FL (US)

(73) Assignee: Tokyo Electron Limited, Tokyo (JP)

(21) Appl. No.: 17/873,745

(22) Filed: Jul. 26, 2022

Related U.S. Application Data
(60) Provisional application No. 63/287,173, filed on Dec. 8, 2021.

(51) Int. Cl. H01L 21/8234; H01L 21/822; H01L 29/66; H01L 29/417; H01L 29/423; H01L 29/786; H01L 29/06

(52) U.S. Cl. CPC H01L 21/823475; H01L 21/8221; H01L 29/66545; H01L 29/66553; H01L 29/41775; H01L 29/42392; H01L 29/78696; H01L 29/0673

(57) ABSTRACT

A method of microfabrication includes forming a stack of source/drain (S/D) contact structures over a substrate. The S/D contact structures are vertically separated. Gate contact structures are formed over the substrate and vertically separated. A first opening is formed so that middle portions of the S/D contact structures are removed while end portions of the S/D contact structures are positioned on opposing sides of the first opening. A layer stack is formed within the first opening, and includes channel structures stacked over the substrate, vertically separated and connected to respective end portions of the S/D contact structures. Second openings are formed, each uncovering a respective side surface of the layer stack and a respective side surface of at least one gate contact structure. Gate structures are formed in the second openings so that each gate structure is connected to a respective gate contact structure and a respective channel structure.

### INCORPORATION BY REFERENCE

This present disclosure claims the benefit of U.S. Provisional Application No. 63/287,173, filed on Dec. 8, 2021, which is incorporated herein by reference in its entirety.

### FIELD OF THE INVENTION

This disclosure relates to microelectronic devices including semiconductor devices, transistors, and integrated circuits, and methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

### SUMMARY

The present disclosure relates to a semiconductor device and a method of forming the same.

According to a first aspect of the disclosure, a method of fabricating a semiconductor device is provided. The method includes forming a stack of source/drain (S/D) contact structures over a substrate such that the S/D contact structures are vertically separated from each other by dielectric material. Gate contact structures are formed over the substrate. The gate contact structures are vertically separated from each other by dielectric material. A first opening is formed in the stack of S/D contact structures so that middle portions of the S/D contact structures are removed while end portions of the S/D contact structures are positioned on opposing sides of the first opening. A layer stack is formed within the first opening. The layer stack includes channel structures that are stacked over the substrate, vertically separated from each other and connected to respective end portions of the S/D contact structures. Second openings are formed, each of which uncovers a respective side surface of the layer stack and a respective side surface of at least one of the gate contact structures. Gate structures are formed in the second openings so that each of the gate structures is connected to a respective gate contact structure and a respective channel structure of the layer stack.

In some embodiments, the forming the S/D contact structures includes forming a first S/D contact structure and a second S/D contact structure that is shorter than the first S/D contact structure in a horizontal direction parallel to a working surface of the substrate.

In some embodiments, a vertical conductive structure is formed that is connected to a first end portion of the first S/D contact structure and is spaced apart, in the horizontal direction, from end portions of the second S/D contact structure.

In some embodiments, the first S/D contact structure is formed over the second S/D contact structure.

In some embodiments, buried power rails are formed below the second S/D contact structure, and the vertical conductive structure is configured to electrically connect the first end portion of the first S/D contact structure to a respective buried power rail.

In some embodiments, the first S/D contact structure is formed below the second S/D contact structure.

In some embodiments, the forming the S/D contact structures includes forming a first S/D contact structure and a second S/D contact structure. The first S/D contact structure and the second S/D contact structure are staggered in a horizontal direction parallel to a working surface of the substrate.

In some embodiments, the forming the gate contact structures includes forming a first gate contact structure and a second gate contact structure that is spaced apart from the first gate contact structure in a horizontal direction parallel to a working surface of the substrate and in a vertical direction perpendicular to the working surface of the substrate.

In some embodiments, a vertical conductive structure is formed that is connected to the first gate contact structure and is spaced apart, in the horizontal direction, from the second gate contact structure.

In some embodiments, the forming the gate structures includes removing sacrificial layers of the layer stack via the second openings. The sacrificial layers are in direct contact with the channel structures. The gate structures are formed around the channel structures.

In some embodiments, inner spacers are formed configured to separate the end portions of the S/D contact structures from respective gate structures.

In some embodiments, isolation structures are formed that are configured to isolate the gate structures from each other and from the substrate.

In some embodiments, sacrificial layers are removed that are in direct contact with one or more first channel structures. A first gate structure is formed around the one or more first channel structures. Sacrificial layers are removed that are in direct contact with one or more second channel structures. A second gate structure is formed around the one or more second channel structures.

In some embodiments, the forming the second openings includes removing end portions of the gate contact structures.

In some embodiments, the forming the layer stack includes epitaxially growing a stack of semiconductor layers, including the channel structures, over the substrate.

In some embodiments, the S/D contact structures have different lengths such that, when viewed from a wiring direction perpendicular to a working surface of the substrate, a given S/D contact structure extends beyond another given S/D contact structure.

In some embodiments, the gate contact structures have different lengths such that, when viewed from a wiring direction perpendicular to a working surface of the substrate, a given gate contact structure extends beyond another given gate contact structure.

In some embodiments, the gate contact structures are offset in a direction parallel to a working surface of the substrate such that, when viewed from a wiring direction perpendicular to the working surface of the substrate, a given pair of gate contact structures are separated.

In some embodiments, at least one of the S/D contact structures and at least one of the gate contact structures include a same structure having extensions in orthogonal directions.

In some embodiments, the channel structures each include a respective source region, a respective channel region and a respective drain region connected serially in a horizontal direction parallel to a working surface of the substrate.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1A shows a top view of a semiconductor device, in accordance with an embodiment of the present disclosure.

FIG. 1B shows a vertical cross-sectional view taken along the line cut AA′ in FIG. 1A, in accordance with an embodiment of the present disclosure.

FIG. 1C shows a vertical cross-sectional view taken along the line cut BB′ in FIG. 1A, in accordance with an embodiment of the present disclosure.

FIG. 1D shows a top view of a semiconductor device, in accordance with another embodiment of the present disclosure.

FIG. 1E shows a vertical cross-sectional view taken along the line cut CC′ in FIG. 1D, in accordance with an embodiment of the present disclosure.

FIG. 1F shows a vertical cross-sectional view taken along the line cut DD′ in FIG. 1D, in accordance with an embodiment of the present disclosure.

FIG. 2 shows a flow chart of a process for manufacturing a semiconductor device, in accordance with some embodiments of the present disclosure.

FIG. 3A shows a top view of a semiconductor device, in accordance with yet another embodiment of the present disclosure.

FIGS. 3B, 3C, 4, 5, 6, 7A, 7B, 8A, 8B, 9 and 10 show cross-sectional views of a semiconductor device at intermediate steps of manufacturing, in accordance with some embodiments of the present disclosure.

FIGS. 11, 12, 13, 14, 15 and 16 show cross-sectional views of a semiconductor device at various intermediate steps of manufacturing, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

3D integration, i.e. the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (CPU (central processing unit), GPU (graphics processing unit), FPGA (field programmable gate array, SoC (System on a chip)) is being pursued.

Techniques disclosed herein include methods of making stacked transistors. Layering the 3D horizontal nanosheet metal, prior to forming the 3D semiconductor nanoplanes, enables the stack height to be extended to N layers. Techniques herein can use a 3D pre-wiring in a first direction (e.g. the x direction) for the source/drain (S/D) directions, while a 3D pre-wiring in a second direction (e.g. the y direction) is used for GAA (gate all around) pre-wiring for the metal gate electrode to provide future connections for circuit elements and routing. Embodiments enable offset metal line stub outs as viewed from a top view (in 3D xy planes for both S/D sides and gate electrode sides as one option, then this is extended to the z direction as 3D Nano planes are stacked). Also enabled are 3D metal lines along one axis to be made with different lengths for each of the metal connections to circuit elements (S/D/Gate). Because these techniques have GAA structure, the gate electrode can be connected on either side perpendicular to the S/D sides. This feature enables high layer stacks of N devices that may be connected compactly from top or pre-metal routing options.

Techniques herein enable 3D horizontal nanosheets with 3D pre-wiring for future S/D regions and also future gate electrode regions prior to 3D transistor formation (e.g. a stack of four nanosheets for two transistors, a stack of eight nanosheets for four transistors, or the like). This process sequence may be repeated for N tall GAA stacks (i.e. a stack of any number of transistors each independently having any number of nanosheets configured as channel structures). Techniques herein include completing pre-metal hookup of S/D and gate, using a GAA structure of a lower transistor, and then sequentially forming a next transistor (using a second channel selective release followed by next layer of an upper transistor and pre-metal hookup of S/D and gate). This process sequence may be repeated for N tall GAA stacks. Devices herein can include any number of nanosheets or transistors stacked in the vertical direction. The pre-wiring of the gate electrode regions may be on both perpendicular sides to the S/D direction since only one hookup is needed due to GAA metal. The pre-wiring of the gate electrode may be staggered as N nanosheets are made.

Embodiments include forming conductive (e.g. metal) gate contact structures and source/drain (S/D) contact structures prior to forming gate-all-around (GAA) transistors. First, metal structures are formed at different levels and different horizontal positions and having different lengths. The metal structures can extend into a foot print of the channel region (nanosheet stack) to enable self-alignment. The initial result, that is for pre-wiring, is conductive structures (lines, rectangles, composite shapes) formed on a substrate within one or more dielectrics. Conductive structures can have offsets relative to each other, and can overlap and extend into a region in which a nanosheet stack for GAA transistors will be formed. The channel region is formed by using photolithography to form an etch mask. Then a directional etch is executed. Such an anisotropic etch cuts through layers (e.g. dielectric and conductive layers) in the channel region. Accordingly, this will enable self-alignment with the conductive structures. Then, a layer stack is formed within the etched out region. By uncovering an underlying layer of silicon or another semiconductor material, a stack of semiconductor layers (e.g. alternating semiconductor layers) can be grown within the opening by epitaxial growth. Opposing sides of one horizontal axis of the nanosheet stack will be used for source/drain contacts, while opposing sides of another horizontal axis (orthogonal) will be used for gate contacts. Though with gate contacts, both gate contacts can be on a same side, offset from each other.

After growing the nanosheets stack within the opening, opposing gate sides are etched, while gate contact metal structures still extend beyond the second etched region. This metal can appear as conductive tabs. With access to the nanosheet stack from the gate side, alternating layers can be isotropically removed and then gate stacks formed on channel structures. Gate metal can be deposited from the side openings. The result is that gate metal will contact channel structures as well as pre-formed metal tabs for overhead wire access. Different gate metals can be used by etch back techniques and dielectric separation. The result is a vertical stack of horizontal nanosheets GAA transistor devices with source, drain, and gate contact tabs already in place for via or contact formation (local interconnects). Note that metal connections to the tabs can extend from the top (above) the transistor or from below such as with buried power rails. Accordingly, pre-wired metal connections can have different lengths depending on whether local interconnects are extending from above or beneath. For example, if local interconnects extend from below, then a lower transistor metal tab will be shorter than an upper level transistor tab so that both can be contacted. Pre-wire metal can benefit from selecting a high temperature compatible metal such as ruthenium.

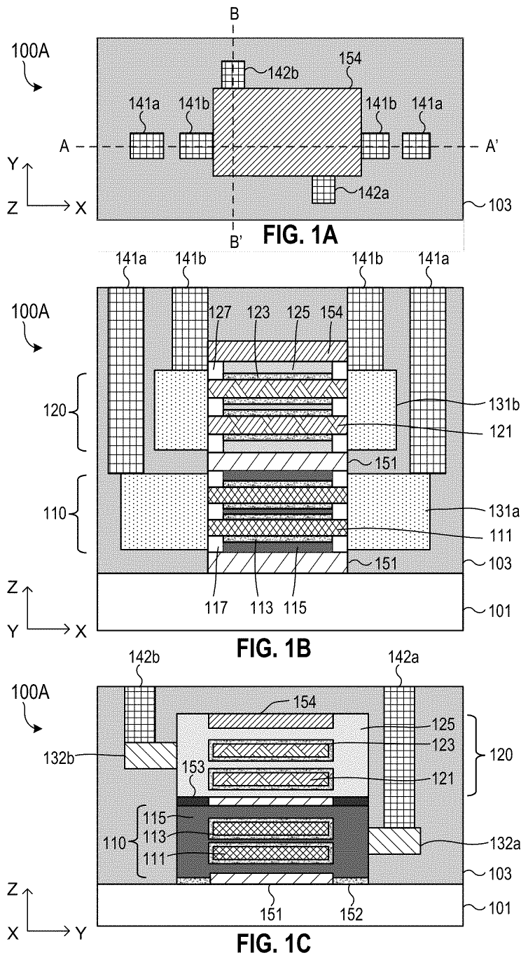

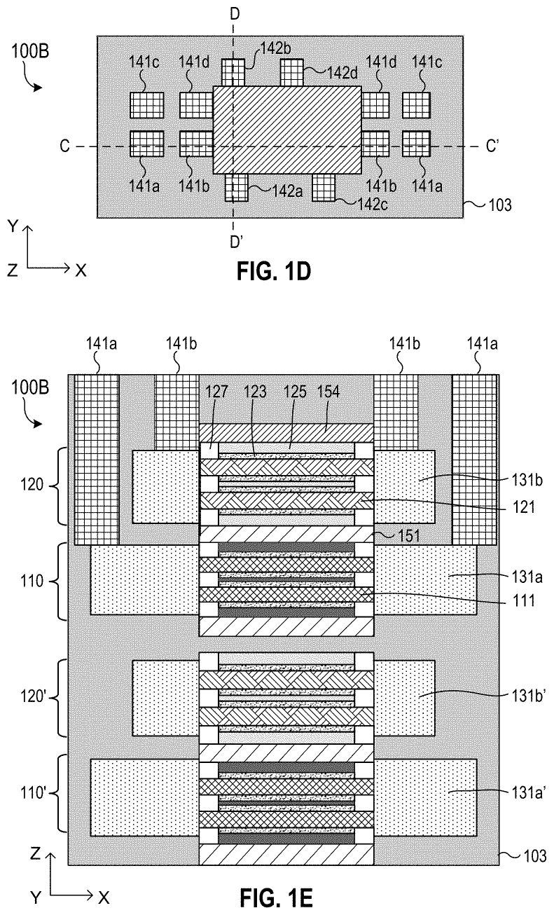

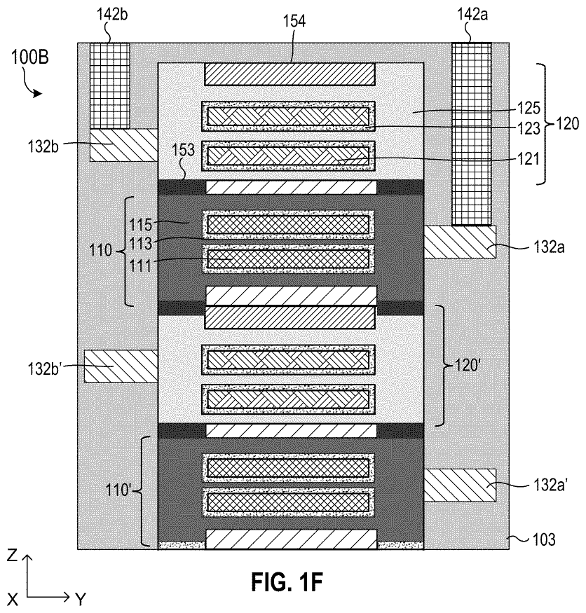

FIG. 1A shows a top view of a semiconductor device 100A, in accordance with an embodiment of the present disclosure. FIG. 1B shows a vertical cross-sectional view in the XZ plane taken along the line cut AA′ in FIG. 1A, in accordance with an embodiment of the present disclosure. FIG. 1C shows a vertical cross-sectional view in the YZ plane taken along the line cut BB′ in FIG. 1A, in accordance with an embodiment of the present disclosure.

As shown, the semiconductor device 100A includes a first transistor 110 disposed over a substrate 101, and a second transistor 120 stacked over the first transistor 110. The first transistor 110 includes one or more (e.g. two) first channel structures 111 surrounded by a first gate structure. For example, the first gate structure includes at least one gate dielectric 113 and at least one gate metal 115. The second transistor 120 includes one or more (e.g. two) second channel structures 121 surrounded by a second gate structure. For example, the second gate structure includes at least one gate dielectric 123 and at least one gate metal 125.

The semiconductor device 100A also includes first S/D contact regions 131a and second S/D contact regions 131b. The first S/D contact regions 131a are disposed on opposing ends of the first channel structures 111 and separated from the first gate structure by first inner spacers 117. The second S/D contact regions 131b are disposed on opposing ends of the second channel structures 121 and separated from the second gate structure by second inner spacers 127. Vertical conductive structures 141a and 141b are disposed on and in direct contact with respective S/D contact regions. In this example, the first S/D contact regions 131a are longer than the second S/D contact regions 131b in the X direction. As a result, the vertical conductive structures 141a are offset or spaced apart from the second S/D contact regions 131b in the X direction. In other words, the vertical conductive structures 141a bypass the second S/D contact regions 131b.

The semiconductor device 100A further includes a first gate contact structure 132a and a second gate contact structure 132b. Vertical conductive structures 142a and 142b are disposed on and in direct contact with a respective gate contact structure. In this example, the first gate contact structure 132a and the second gate contact structure 132b are offset or spaced apart from each other both in the Y direction and in the Z direction. As a result, the first gate contact structure 132a and the second gate contact structure 132b are staggered in the Y direction. The vertical conductive structures 142a and 142b are respectively offset from the second gate contact structure 132b and the first gate contact structure 132a in the Y direction.

Note that the semiconductor device 100A can include one or more dielectric materials, e.g. 103, 113, 117, 123, 127, 151, 152, 153, 154, etc. A given dielectric material may also be referred to as an isolation structure, an isolation layer, a diffusion break, an inner spacer, a gate dielectric, a capping layer, etc. depending on functions thereof. For example, the dielectric material 153 can separate the first gate structure from the second gate structure and thus be referred to as an isolation structure. The dielectric material 154 can be referred to as a capping layer. Additionally, some of the one or more dielectric materials may include identical materials or may include different materials. For example, the first inner spacers 117 and the second inner spacers 127 may include a same material, which may be different from the at least one gate dielectric 113.

The line cut BB′ does not cut through the vertical conductive structure 142a in FIG. 1A, but the vertical conductive structure 142a is shown in FIG. 1C for illustrative purposes. It should be understood that relative positions of the vertical conductive structures 142a and 142b are flexible. For example, the vertical conductive structures 142a and 142b can be positioned on a same side of the dielectric material 154 or positioned on opposing sides of the dielectric material 154. While shown to be in contact with the dielectric material 154 in FIG. 1A, the vertical conductive structure 142a and the vertical conductive structure 142b can be spaced apart from the dielectric material 154.

The line cut AA′ cuts through the vertical conductive structures 141a and 141b in FIG. 1A. It should be understood that relative positions of the vertical conductive structures 142a and 142b are flexible. For example, one or more of the vertical conductive structures 141a and 141b can be disposed on a different XZ plane(s).

In some embodiments (not shown), the first S/D contact regions 131a and the second S/D contact regions 131b may be staggered in the Y direction. Accordingly, the vertical conductive structures 141a and the vertical conductive structures 141b can be disposed in different XZ planes. That is, the vertical conductive structures 141a can be offset from respective vertical conductive structures 141b in the Y direction. Additionally, the first S/D contact regions 131a and the second S/D contact regions 131b may have a same length or different length in the X direction. When the first S/D contact regions 131a and the second S/D contact regions 131b have the same length, the vertical conductive structures 141a can be offset from respective vertical conductive structures 141b in the Y direction while having no offset from the respective vertical conductive structures 141b in the X direction.

In some embodiments (not shown), the first S/D contact regions 131a are shorter than the second S/D contact regions 131b in the X direction. Accordingly, buried power rails can be formed below the second S/D contact regions 131b, for example in the substrate 101. As a result, the vertical conductive structures 141a and the vertical conductive structures 141b are respectively disposed below the first S/D contact regions 131a and the second S/D contact regions 131b and are connected to respective buried power rails. In this case, the vertical conductive structures 141b bypass the first S/D contact regions 131a. Similarly, the vertical conductive structures 142a and the vertical conductive structures 142b can be respectively disposed below the first gate contact structure 132a and the second gate contact structure 132b and connected to respective buried power rails.

In some embodiments, the first channel structures 111 and the second channel structures 121 can each include a respective source region, a respective channel region and a respective drain region connected serially (not shown), with or without junctions. The first inner spacers 117 can be configured to isolate respective source regions and respective drain regions from respective first gate structures. The second inner spacers 127 can be configured to isolate respective source regions and respective drain regions from respective second gate structures.

In some embodiments, the channel structures can include different chemical compositions from one another. That is, the channel structures can include different semiconductor materials, different dopants and/or different dopant concentration profiles. For instance, the first channel structures 111 may include a different chemical composition from the second channel structures 121. In one example, the first channel structures 111 include n-type silicon while the second channel structures 121 include p-type silicon. In another example, the first channel structures 111 include p-type silicon while the second channel structures 121 include n-type silicon. Additionally, the channel structures can have various shapes or geometry. For example, the channel structures can be nanosheets.

FIG. 1D shows a top view of a semiconductor device 100B, in accordance with an embodiment of the present disclosure. FIG. 1E shows a vertical cross-sectional view in the XZ plane taken along the line cut CC′ in FIG. 1D, in accordance with an embodiment of the present disclosure. FIG. 1F shows a vertical cross-sectional view in the YZ plane taken along the line cut DD′ in FIG. 1D, in accordance with an embodiment of the present disclosure.

Note that embodiments of the semiconductor device 100B are similar to embodiments of the semiconductor device 100A. Identical or similar components are labeled with identical or similar numerals. For example, the semiconductor device 100B includes the first transistor 110 and the second transistor 120. Note that the semiconductor device 100B also includes the substrate 101 which is not shown here.

The semiconductor device 100B further includes a third transistor 110′ and a fourth transistor 120′, which are similar to the first transistor 110 and the second transistor 120 respectively. Third S/D contact regions 131a′ and fourth S/D contact regions 131b′ are similar to the first S/D contact regions 131a and the second S/D contact regions 131b respectively. A third gate contact structure 132a′ and a fourth gate contact structure 132b′ are similar to the first gate contact structure 132a and the second gate contact structure 132b respectively. Thus, descriptions will be omitted herein for simplicity purposes.

In the example of FIG. 1E, the third S/D contact regions 131a′ are longer than the fourth S/D contact regions 131b′ in the X direction. While not shown, the first S/D contact regions 131a and the third S/D contact regions 131a′ can be staggered in the Y direction. As a result, vertical conductive structures 141c are offset from the vertical conductive structures 141a in the Y direction as illustrated in FIG. 1D and thus not shown in the cross-sectional view of FIG. 1E. Similarly, the second S/D contact regions 131b and the fourth S/D contact regions 131b′ can be staggered in the Y direction such that vertical conductive structures 141d are offset from the vertical conductive structures 141b in the Y direction.

In FIG. 1F, while not shown, the first gate contact structure 132a and the third gate contact structure 132a′ can be staggered in the X direction. As a result, a vertical conductive structure 142c is offset from the vertical conductive structure 142a in the X direction as illustrated in FIG. 1D and thus not shown in the cross-sectional view of FIG. 1F. Similarly, the second gate contact structure 132b and the fourth gate contact structure 132b′ can be staggered in the X direction such that a vertical conductive structure 142d is offset from the vertical conductive structure 142b in the X direction.

In some embodiments (not shown), buried power rails can be formed below the third transistor 110′. Similarly, the vertical conductive structures 141c, 141d, 142c and 142d can be disposed below respective S/D or gate contact structures and configured to connect a respective buried power rail.

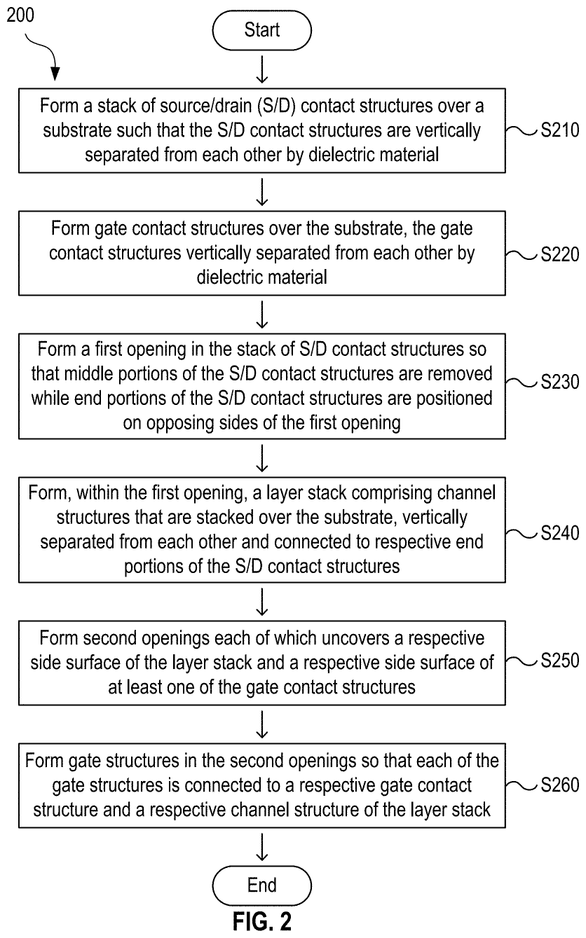

FIG. 2 shows a flow chart of a process 200 for manufacturing a semiconductor device such as the semiconductor device 100A, 100B and the like, in accordance with some embodiments of the present disclosure. The process 200 begins with Step S210 by forming a stack of source/drain (S/D) contact structures over a substrate such that the S/D contact structures are vertically separated from each other by dielectric material. At Step S220, gate contact structures are formed over the substrate. The gate contact structures are vertically separated from each other by dielectric material. At Step S230, a first opening is formed in the stack of S/D contact structures so that middle portions of the S/D contact structures are removed while end portions of the S/D contact structures are positioned on opposing sides of the first opening. At Step S240, a layer stack is formed within the first opening. The layer stack includes channel structures that are stacked over the substrate, vertically separated from each other and connected to respective end portions of the S/D contact structures. At Step S250, second openings are formed, each of which uncovers a respective side surface of the layer stack and a respective side surface of at least one of the gate contact structures. At Step S260, gate structures are formed in the second openings so that each of the gate structures is connected to a respective gate contact structure and a respective channel structure of the layer stack.

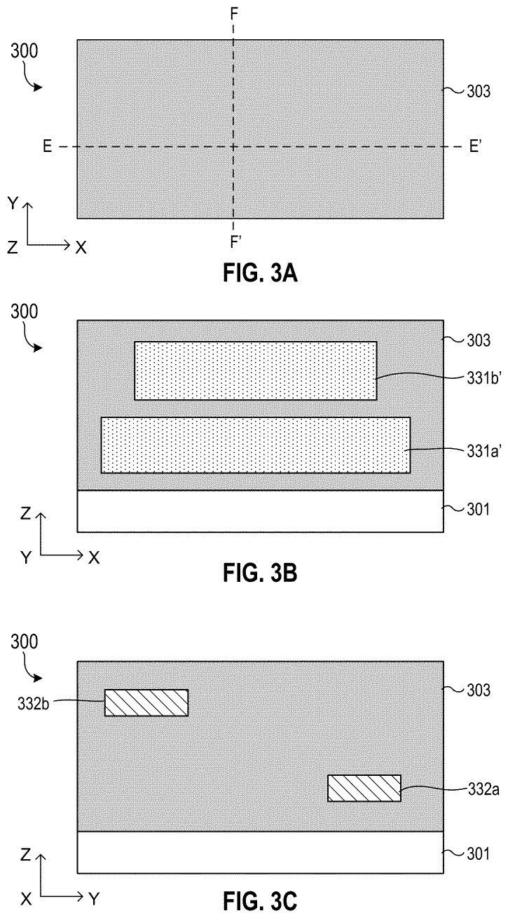

FIG. 3A shows a top view of a semiconductor device 300, which can eventually become the semiconductor device 100A, in accordance with an embodiment of the present disclosure. FIG. 3B shows a vertical cross-sectional view in the XZ plane taken along the line cut EE′ in FIG. 1A, in accordance with an embodiment of the present disclosure. FIG. 1C shows a vertical cross-sectional view in the YZ plane taken along the line cut BB′ in FIG. 1A, in accordance with an embodiment of the present disclosure.

As shown, S/D contact structures (e.g. 331a′ and 331b′) can be formed over a substrate 301 and separated from each other by a dielectric material 303. The S/D contact structures can extend along a first horizontal direction, such as the X direction. In this example, a first S/D contact structure 331a′ is positioned below a second S/D contact structure 331b′ in the Z direction while being longer than the second S/D contact structure 331b′ in the X direction.

Gate contact structures (e.g. 332a and 332b) can be formed over the substrate 301 and separated from each other by the dielectric material 303. The gate contact structures can extend along a second horizontal direction, such as the Y direction. In this example, a first gate contact structure 332a is positioned below a second gate contact structure 332b in the Z direction while being offset from the second gate contact structure 332b in the Y direction. That is, the first gate contact structure 332a and the second gate contact structure 332b are staggered in the Y direction.

In some embodiments, the substrate 301 can correspond to the substrate 101. The dielectric material 303 can correspond to the dielectric material 103. The first S/D contact structure 331a′ and the second S/D contact structure 331b′ can be used to form the first S/D contact region 131a and the second S/D contact regions 131b respectively. The first gate contact structure 332a and the second gate contact structure 332b can correspond to, or be used to form, the first gate contact structure 132a and the second gate contact structure 132b respectively.

In one embodiment, the S/D contact structures and the gate contact structures are formed separately, e.g. using different masks and different lithographic patterning steps. In another embodiment, the S/D contact structures and the gate contact structures can be formed in common processing steps. For example, the first S/D contact structure 331a′ and the first gate contact structure 332a may be formed using a common mask and formed in common etching and deposition steps. Consequently, the first S/D contact structure 331a′ and the first gate contact structure 332a may have a same thickness in the Z direction.

In the examples of FIGS. 3A-3C, a stack of 2 metals high is formed in a dielectric layer as shown on a semiconductor substrate along the X direction and will be metal S/D future connection regions. Another stack of 2 metals high is formed in the dielectric layer as shown on a semiconductor substrate along the Y direction and will be metal gate electrode regions. Note that the gate metal pre-wiring can be arranged on sides (e.g. the +Y and −Y sides) perpendicular to S/D sides (e.g. the +X and −X sides).

When viewed from a wiring direction (e.g. the Z direction), the first gate contact structure 332a and the second gate contact structure 332b are separated from each other in the example of FIG. 3C. In other examples (not shown), when viewed from the Z direction, the first gate contact structure 332a and the second gate contact structure 332b can have an overlapping portion(s), which can be removed by future etching. In other words, the first gate contact structure 332a and the second gate contact structure 332b may extend into an area for future channel structures.

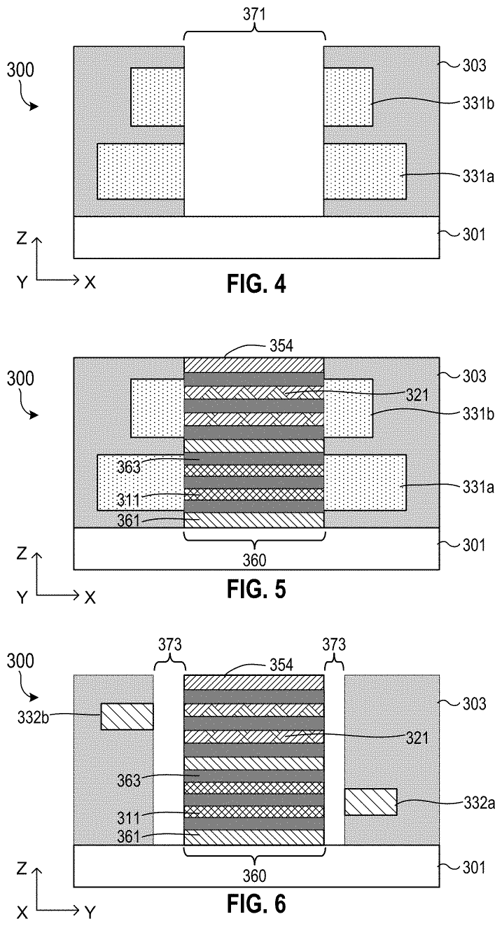

In FIG. 4, a first opening 371 is formed over the substrate 301, for example by a directional etching process using a photoresist mask (not shown). As a result, middle portions of the S/D contact structures are removed while end portions of the S/D contact structures are positioned on opposing sides of the first opening 371. Particularly, end portions 331a and 331b of the S/D contact structures (331a′ and 331b′) can respectively correspond to the S/D contact regions 131a and 131b and will respectively be referred to as first S/D contact regions 331a and second S/D contact regions 331b hereinafter. In some embodiments (not shown), end portions of the first gate contact structure 332a and the second gate contact structure 332b may be removed by the directional etching process.

In FIG. 5, a layer stack 360 is formed within the first opening 371. The layer stack 360 can include channel structures (e.g. 311 and 321) that are stacked over the substrate 301, separated from each other and connected to respective end portions of the S/D contact structures. For example, the first S/D contact regions 331a are disposed on opposing sides of first channel structures 311. The second S/D contact regions 331b are disposed on opposing sides of second channel structures 321. The layer stack 360 can also include sacrificial layers (e.g. 361 and 363) which can be used to form gate structures, inner spacers, isolation structures, etc. A dielectric material 354 (also referred to as a capping layer) can be formed over the layer stack 360.

In some embodiments, the layer stack 360 can be formed by epitaxially growing a stack of semiconductor layers, including alternating channel structures and sacrificial layers. In a non-limiting example, the substrate 101 is a silicon substrate. The first channel structures 311 include p-type silicon while the second channel structures 321 include n-type silicon. Sacrificial layers 363 can include silicon germanium (noted as SiGe1) while sacrificial layers 361 can include silicon germanium (noted as SiGe2). SiGe1 and SiGe2 can have different ratios of Si to Ge so as to have etch selectivity. For instance, SiGe1 can include 75 mol % of Si and 25 mol % of Ge, while SiGe2 can include 10 mol % of Si and 90 mol % of Ge.

“Epitaxial growth”, “epitaxial deposition”, “epitaxially growing”, “epitaxially forming” or “epitaxy” as used herein generally refers to a type of crystal growth or material deposition in which a crystalline layer is formed over a seed layer that is crystalline. Crystalline characteristics (e.g. crystal orientation) of the crystalline layer are related to or dictated by crystalline characteristics of the seed layer. Particularly, a semiconductor material can be epitaxially grown on a surface of another semiconductor layer that is crystalline. In some embodiments, epitaxial growth can be selective such that a semiconductor material may only be epitaxially grown on another semiconductor surface and generally do not deposit on exposed surfaces of non-semiconductor materials, such as silicon oxide, silicon nitride, and the like. Epitaxial growth can be accomplished by molecular beam epitaxy, vapor-phase epitaxy, liquid-phase epitaxy, or the like. Si, SiGe, Ge and other semiconductor materials can be doped during epitaxial growth (in situ) by addition of dopants. For example in vapor-phase epitaxy, a dopant vapor can be added to the gas source.

In FIG. 6, second openings 373 are formed to uncover, from side surfaces, the layer stack 360 and the gate contact structures (e.g. 332a and 332b). For example, a photoresist mask (not shown) can be used to etch to the substrate 301 on both sides (e.g. the +X and −X sides) perpendicular to S/D sides (e.g. the +Y and −Y sides). Note that the layer stack 360 is supported on the S/D sides. The gate electrode metal (e.g. 332a and 332b) can be self-aligned for hookup after GAA structure is made in future steps.

In one embodiment, the first gate contact structure 332a and the second gate contact structure 332b may be partially etched to be uncovered from side surfaces by the second openings 373. Thus, the first gate contact structure 332a and the second gate contact structure 332b can respectively correspond to the first gate contact structure 132a and the second gate contact structure 132b. In another embodiment, the first gate contact structure 332a and the second gate contact structure 332b are not etched, but are still uncovered from side surfaces by the second openings 373.

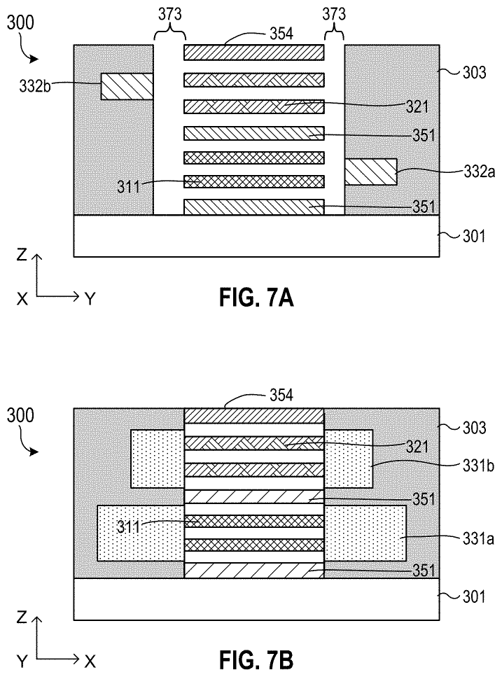

FIGS. 7A and 7B respectively show cross-sectional views in the XZ plane and the YZ plane of the semiconductor device 300 after the sacrificial layers 361 are replaced with a dielectric material 351 and the sacrificial layers 363 are removed via the second openings 373. For example, this can be accomplished by SiGe2 removal (e.g. removing the sacrificial layers 361), then dielectric deposition (e.g. forming the dielectric material 351) and etching excessive dielectric to complete isolation of the device stack to the substrate 301 as well as isolation between 3D nanosheet device types. SiGe removal can also be executed via the second openings 373. It should be noted that remaining layers (e.g. the channel structures) of the layer stack 360 are supported on the S/D sides. The dielectric material 351 (also referred to as isolation structures) can correspond to the dielectric material 151.

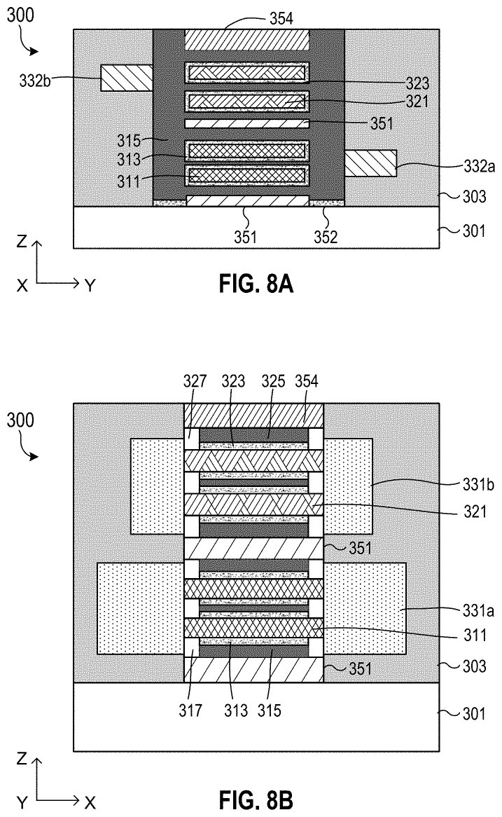

In FIGS. 8A and 8B, selective dielectric deposition is executed for S/D metal regions (e.g. the first S/D contact regions 331a and the second S/D contact regions 331b). This provides inner spacers (e.g. 317 and 327) prior to gate dielectric/gate electrode formation. First inner spacers 317 and second inner spacers 327 can respectively correspond to the first inner spacers 117 and the second inner spacers 127.

Then, selective high-k dielectric deposition is executed, for example on silicon. As a result, at least one gate dielectric 313 and at least one gate dielectric 323 are formed around the first channel structures 311 (e.g. p-type silicon) and the second channel structures 321 (e.g. n-type silicon) respectively. At least one dielectric material 352 is formed on the substrate 301 (e.g. silicon). In this example, the at least one gate dielectric 313, the at least one gate dielectric 323 and the at least one dielectric material 352 can be formed simultaneously and thus include at least one identical dielectric material. In some embodiments, the at least one gate dielectric 313 and the at least one gate dielectric 323 can respectively correspond to the at least one gate dielectric 113 and the at least one gate dielectric 123. The at least one dielectric material 352 can correspond to the dielectric material 152.

Subsequently, at least one gate metal 315 is formed all around the at least one gate dielectric 313 and the at least one gate dielectric 323 in addition to filling the second openings 373.

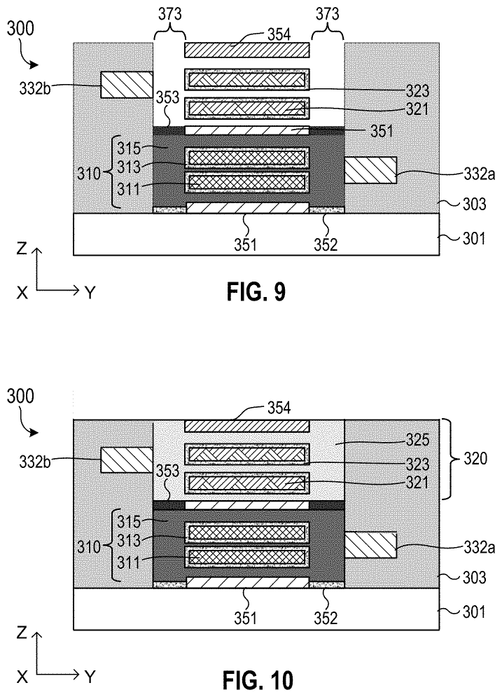

In FIG. 9, the at least one gate metal 315 is etched back, for example to the dielectric material 351 (the isolation structure). As a result, a first transistor 310 is formed. Note that the at least one gate metal 315 is connected to both the first channel structures 311 and the first gate contact structure 332a. A dielectric material 353 is then formed over the at least one gate metal 315 for future isolation. Note that the at least one gate dielectric 323 is uncovered. The first transistor 310 can correspond to the first transistor 110. The at least one gate metal 315 can correspond to the at least one gate metal 115. The dielectric material 353 can correspond to the dielectric material 153.

In FIG. 10, at least one gate metal 325 is deposited to surround the at least one gate dielectric 323 and also fill up vertical cavity (e.g. the second openings 373), optionally followed by a final CMP (chemical mechanical polishing) process. As a result, a second transistor 320 is formed over the first transistor 310. The second transistor 320 can correspond to the second transistor 120. The at least one gate metal 325 can correspond to the at least one gate metal 125. In some embodiments, the at least one gate dielectric 323 may be replaced with another dielectric(s) before the at least one gate metal 325 is formed.

While not shown, vertical conductive structures, which correspond to the vertical conductive structures 141a, 141b, 142a and 142b, can be formed. For example, a dielectric deposition can be executed to deposit the dielectric material 103, followed by CMP and then using a metal mask to make contact from top as one option or the pre-wiring (e.g. 141a, 141b, 142a and 142b). As a result, the semiconductor device 300 can eventually become the semiconductor device 100A.

In some embodiments (not shown), the first S/D contact regions 331a and the second S/D contact regions 331b may be staggered in the Y direction. In some embodiments (not shown), the first S/D contact regions 331a are shorter than the second S/D contact regions 331b in the X direction. Similar discussions have been provided above for the semiconductor device 100A and will thus be omitted herein for simplicity purposes.

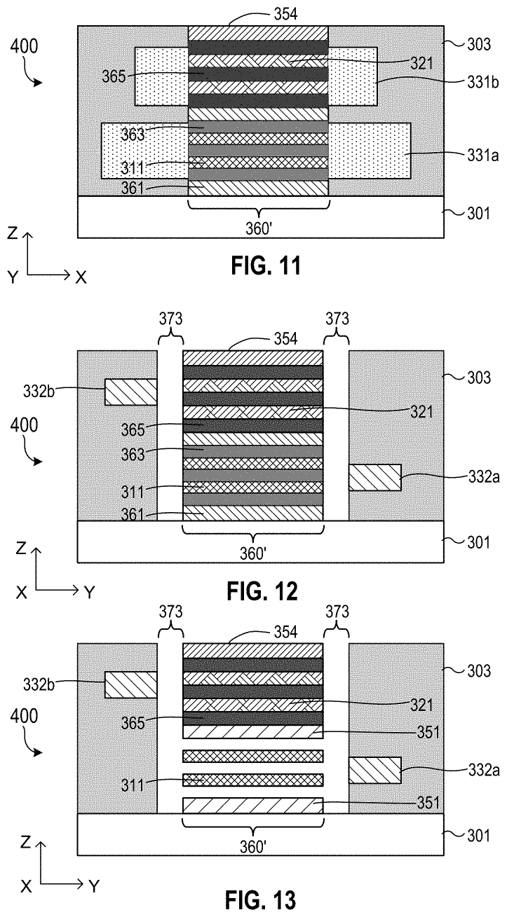

FIGS. 11, 12, 13, 14, 15 and 16 show cross-sectional views of a semiconductor device 400, which can eventually become the semiconductor device 100A, at various intermediate steps of manufacturing, in accordance with some embodiments of the present disclosure. Embodiments herein include 3D horizontal nanosheet with 3D pre-wiring for future S/D regions and also future gate electrode regions prior to 3D transistor formation of a nanosheet stack of two transistors using a GAA lower transistor. Pre-metal hookup of S/D and gate is completed, before sequentially forming an upper transistor (using a second channel selective release, followed by a next layer of the upper transistor and pre-metal hookup of S/D and gate. Such a process sequence may be repeated for N tall GAA stacks.

The semiconductor device 400 can be obtained by forming a layer stack 360′ within the first opening 371 in FIG. 4. Therefore, embodiments of the semiconductor device 400 in FIG. 11 are similar to embodiments of the semiconductor device 300 in FIG. 5, but sacrificial layers 365, instead of the sacrificial layers 363, are formed in direct contact with (on or below) the second channel structures 321. The sacrificial layers 365 are configured to have etch selectivity relative to the sacrificial layers 363. For example, the sacrificial layers 365 can include silicon germanium (noted as SiGe3). SiGe1, SiGe2 and SiGe3 can have different ratios of Si to Ge. For instance, SiGe1 can include 75 mol % of Si and 25 mol % of Ge. SiGe2 can include 10 mol % of Si and 90 mol % of Ge. SiGe3 can include 45 mol % of Si and 55 mol % of Ge.

In FIG. 12, the second openings 373 are formed to uncover, from side surfaces, the layer stack 360′ and the gate contact structures (e.g. 332a and 332b), similar to FIG. 6.

In FIG. 13, the sacrificial layers 361 are replaced with the dielectric material 351 to form isolation structures via the second openings 373. The sacrificial layers 363 are also selectively removed via the second openings 373 to uncover the first channel structures 311.

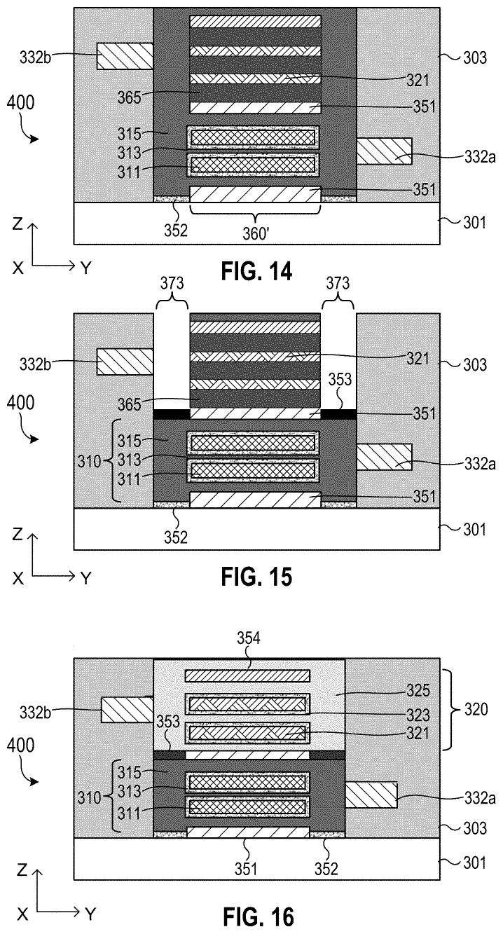

In FIG. 14, the at least one gate dielectric 313 is formed around the first channel structures 311, for example selectively on silicon. While not shown, first inner spacers, which correspond to the first inner spacers 117, can be formed. The at least one gate metal 315 is then formed.

In FIG. 15, the at least one gate metal 315 is etched back to the dielectric material 351 before the dielectric material 353 is formed on the at least one gate metal 315. As a result, the first transistor 310 is formed.

In FIG. 16, the sacrificial layers 361 are removed to uncover the second channel structures 321. Then, the at least one gate dielectric 323 is formed around the second channel structures 321. While not shown, second inner spacers, which correspond to the second inner spacers 127, can be formed. The at least one gate metal 325 is then formed. Consequently, the second transistor 320 is formed. Note that the semiconductor device 400 in FIG. 16 can correspond to the semiconductor device 300 in FIG. 10. Similarly, vertical conductive structures, which correspond to the vertical conductive structures 141a, 141b, 142a and 142b, can be formed. As a result, the semiconductor device 400 can eventually become the semiconductor device 100A.

While not shown, the semiconductor device 100B in FIG. 1D-1F can be formed using processes shown in FIGS. 3A-3C, 4-6, 7A-7B and 8-16. As mentioned earlier, buried power rails may be formed. In a non-limiting example, the semiconductor device 100B includes a stack of four transistors with eight nanosheets (i.e. eight S/D contacts with four gate electrode contacts), which can be used to make a dual CFET stack with four source and four drain connects and four gate electrode connection (top connection can be combined with lower routing connections in the pre-wiring concept for lower S/D regions).

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method of fabricating a semiconductor device, the method comprising:
forming a stack of source/drain (S/D) contact structures over a substrate such that the S/D contact structures are vertically separated from each other by dielectric material;
forming gate contact structures over the substrate, the gate contact structures vertically separated from each other by dielectric material;
forming a first opening in the stack of S/D contact structures so that middle portions of the S/D contact structures are removed while end portions of the S/D contact structures are positioned on opposing sides of the first opening;
forming, within the first opening, a layer stack comprising channel structures that are stacked over the substrate, vertically separated from each other and connected to respective end portions of the S/D contact structures;
forming second openings each of which uncovers a respective side surface of the layer stack and a respective side surface of at least one of the gate contact structures; and
forming gate structures in the second openings so that each of the gate structures is connected to a respective gate contact structure and a respective channel structure of the layer stack.

2. The method of claim 1, wherein the forming the S/D contact structures comprises forming a first S/D contact structure and a second S/D contact structure that is shorter than the first S/D contact structure in a horizontal direction parallel to a working surface of the substrate.

3. The method of claim 2, further comprising forming a vertical conductive structure that is connected to a first end portion of the first S/D contact structure and is spaced apart, in the horizontal direction, from end portions of the second S/D contact structure.

4. The method of claim 3, wherein the first S/D contact structure is formed over the second S/D contact structure.

5. The method of claim 4, further comprising forming buried power rails below the second S/D contact structure, wherein the vertical conductive structure is configured to electrically connect the first end portion of the first S/D contact structure to a respective buried power rail.

6. The method of claim 3, wherein the first S/D contact structure is formed below the second S/D contact structure.

7. The method of claim 1, wherein the forming the S/D contact structures comprises forming a first S/D contact structure and a second S/D contact structure, wherein the first S/D contact structure and the second S/D contact structure are staggered in a horizontal direction parallel to a working surface of the substrate.

8. The method of claim 1, wherein the forming the gate contact structures comprises forming a first gate contact structure and a second gate contact structure that is spaced apart from the first gate contact structure in a horizontal direction parallel to a working surface of the substrate and in a vertical direction perpendicular to the working surface of the substrate.

9. The method of claim 8, further comprising forming a vertical conductive structure that is connected to the first gate contact structure and is spaced apart, in the horizontal direction, from the second gate contact structure.

10. The method of claim 1, wherein the forming the gate structures comprises:
removing sacrificial layers of the layer stack via the second openings, the sacrificial layers being in direct contact with the channel structures; and
forming the gate structures around the channel structures.

11. The method of claim 10, further comprising forming inner spacers configured to separate the end portions of the S/D contact structures from respective gate structures.

12. The method of claim 10, further comprising forming isolation structures configured to isolate the gate structures from each other and from the substrate.

13. The method of claim 10, further comprising:
removing sacrificial layers that are in direct contact with one or more first channel structures;
forming a first gate structure around the one or more first channel structures;
removing sacrificial layers that are in direct contact with one or more second channel structures; and
forming a second gate structure around the one or more second channel structures.

14. The method of claim 10, wherein the forming the second openings comprises removing end portions of the gate contact structures.

15. The method of claim 1, wherein the forming the layer stack comprises epitaxially growing a stack of semiconductor layers, including the channel structures, over the substrate.

16. The method of claim 1, wherein the S/D contact structures have different lengths such that, when viewed from a wiring direction perpendicular to a working surface of the substrate, a given S/D contact structure extends beyond another given S/D contact structure.

17. The method of claim 1, wherein the gate contact structures have different lengths such that, when viewed from a wiring direction perpendicular to a working surface of the substrate, a given gate contact structure extends beyond another given gate contact structure.

18. The method of claim 1, wherein the gate contact structures are offset in a direction parallel to a working surface of the substrate such that, when viewed from a wiring direction perpendicular to the working surface of the substrate, a given pair of gate contact structures are separated.

19. The method of claim 1, wherein at least one of the S/D contact structures and at least one of the gate contact structures comprise a same structure having extensions in orthogonal directions.

20. The method of claim 1, wherein the channel structures each include a respective source region, a respective channel region and a respective drain region connected serially in a horizontal direction parallel to a working surface of the substrate.
